(19) United States
(12) Patent Application Publication
(10) Pub. No.: US 2026/0026124 A1
(43) Pub. Date: Jan. 22, 2026

(54) IMAGE SENSOR WITH REDUCED HYBRID BOND COUPLING

(71) Applicant: OMNIVISION TECHNOLOGIES, INC., Santa Clara, CA (US)

(72) Inventors: Takayuki Goto, Foster City, CA (US); Keiji Mabuchi, Cupertino, CA (US)

(21) Appl. No.: 18/776,766

(22) Filed: Jul. 18, 2024

(51) Int. Cl. H01L 27/146; H04N 25/77

(52) U.S. Cl. CPC H10F 39/809; H04N 25/77; H10F 39/18; H10F 39/8037; H10F 39/811

(57) ABSTRACT

An image sensor comprising a first die, a second die, and a plurality of pixel cells arranged in rows and columns to form a pixel cell array is described. The first die and the second die are stacked to form a bonding interface disposed therebetween. A first pixel cell included in the plurality of pixel cells includes a photodiode, disposed within the first die, configured to photogenerate image charge in response to incident light, a flighting diffusion, disposed within the first die, coupled to receive the image charge, and a lateral overflow integration capacitor, disposed within the second die, selectively coupled to the floating diffusion through a first bonding connection formed at the bonding interface.

### TECHNICAL FIELD

This disclosure relates generally to image sensors, and in particular but not exclusively, relates to CMOS image sensors and applications thereof.

### BACKGROUND INFORMATION

Image sensors are one type of semiconductor device that have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing. However, it is appreciated that many of these metrics are inversely related. For example, pixel size may be increased to improve dynamic range but have increased noise. In another example, resolution may be increased by increasing the number of pixels, but if pixel size is maintained then the physical size of the image sensor increases. Accordingly, improving one or more performance metrics of semiconductor devices such as image sensors while mitigating adverse effects on other performance metrics remains challenging.

The typical image sensor operates in response to image light reflected from an external scene being incident upon the image sensor. The image sensor includes an array of pixels having photosensitive elements (e.g., photodiodes) that absorb a portion of the incident image light and generate image charge (e.g., electrons or holes) upon absorption of the image light. The image charge (e.g., electrons or holes) photogenerated by the pixels may be measured as analog output image signals on column bit lines that vary as a function of the incident image light. In other words, the amount of image charge generated is proportional to the intensity of the image light, which is readout as analog image signals from the column bit lines and converted to digital values to produce digital images (i.e., image data) representative of the external scene.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1A illustrates a image sensor with reduced hybrid bond coupling, in accordance with an embodiment of the disclosure.

FIG. 1B illustrates an example circuit diagram representative of a pixel cell included in a plurality of pixel cells of the image sensor of FIG. 1A, in accordance with an embodiment of the disclosure.

FIG. 1C illustrates a cross-sectional view of a pixel cell included in the plurality of pixel cells of the image sensor illustrated in FIG. 1A that is represented by the example circuit diagram illustrated in FIG. 1B, in accordance with an embodiment of the disclosure.

FIG. 2A illustrates a cross-sectional view of a pixel cell with a metal-insulator-metal LOFIC, in accordance with an embodiment of the disclosure.

FIG. 2B illustrates an alternative configuration of a pixel cell illustrated in FIG. 2A, in accordance with an embodiment of the disclosure.

FIG. 3A illustrates a plan view of a bonding interface formed between first die and second die, in accordance with an embodiment of the disclosure.

FIG. 3B illustrates an expanded view of the plan view illustrated in FIG. 3B that further shows plurality of metal wires coupled to plurality of dummy bonding connections for an image sensor with reduced hybrid bond coupling, in accordance with an embodiment of the disclosure.

FIG. 3C illustrates a cross-sectional view extending through a bonding interface along line Y1-Y1′ shown in FIG. 3B, in accordance with an embodiment of the disclosure.

FIG. 3D illustrates a cross-sectional view extending through a bonding interface along line X1-X1′ shown in FIG. 3B, in accordance with an embodiment of the disclosure.

FIG. 4 illustrates a modified arrangement of plurality of metal wires relative to the expanded view shown in FIG. 3B for an image sensor with reduced hybrid bond coupling, in accordance with an embodiment of the disclosure.

### DETAILED DESCRIPTION

Embodiments of an apparatus, system, and method each related to an image sensor with reduced hybrid bond coupling are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Spatially relative terms, such as “beneath,” “below,” “over,” “under,” “above,” “upper,” “top,” “bottom,” “left,” “right,” “center,” “middle,” and the like, may be used herein for ease of description to describe one element or feature's relationship relative to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device may be otherwise oriented (rotated ninety degrees or at other orientations) and the spatially relative descriptors used herein are interpreted accordingly. In addition, it will also be understood that when an element is referred to as being “between” two other elements, it can be the only element between the two other elements, or one or more intervening elements may also be present.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Stacked image sensors (e.g., complementary metal-oxide semiconductor image sensors utilizing two or more vertically stacked dies or wafers) require electrical connections between components of stacked dies to form circuitries and facilitate operation (e.g., to capture an image or video of an external scene). One suitable circuit coupling technology is “hybrid bond technology” which provides metal-to-metal and dielectric-to-dielectric bonding between different dies. Specifically, interconnections may be formed via a direct bond process by which exposed surfaces of metals (e.g., Au, Cu, Al, metal alloys, other metals, and/or combinations thereof) embedded within a dielectric layer of different dies are placed in direct contact. One or more thermally processes may be applied to the stacked image sensor to cause dielectric-to-dielectric bonding (e.g., covalent bonding) between the dielectric layer of the different dies and metal-to-metal bonding (e.g., metallic bonding) between the metals of the different dies resulting in the different dies being permanently affixed together while forming one or more interconnections extending between the different dies.

Hybrid bond technology allows for increased density of interconnections between different dies compared to other circuit coupling technology (e.g., through-silicon vias), which is particularly beneficial for stacked image sensors as the number of interconnections is directly correlated to the number of photodiodes. However, it was found that coupling or crosstalk between interconnections increases in tandem with interconnection density, which may have an adverse effect on image sensor operation and/or performance. Put in another way, coupling between adjacent interconnections proximate to a bonding interface between different dies (i.e., hybrid bond coupling) of a stacked image sensor may result in significant crosstalk between image signals of adjacent pixels of the stacked image sensor. Crosstalk can have an adverse effect on readout (e.g., measurement of image signals propagating between different dies of the stacked image sensor) or otherwise affect performance and/or operation of a stacked image sensor.

This issue of crosstalk is particularly pertinent for stacked image sensors described in embodiments of the disclosure in which pixel-level or pixel cell-level hybrid bonding is desired such that individual pixels or groups of pixels may be read out across dies in a timely and accurate manner. For example, in some embodiments, photosensitive elements (e.g., photodiodes such as pinned photodiodes) is included in a first die to generate image charge in response to incident light while a lateral overflow integration capacitor (LOFIC) is included in a second die to receive excess image charge (e.g., to facilitate high-dynamic range imaging). Accordingly, an interconnection between photodiodes of the first die and a LOFIC of the second die for a given pixel cell is needed to transfer excess image charge generated by the photodiode to the LOFIC (e.g., pixel-cell level hybrid bonding). However, as pixel cell size decreases, crosstalk between interconnections increases. Described herein are embodiments of an image sensor including a first die and a second die (e.g., a stacked image sensor) with reduced hybrid bond coupling.

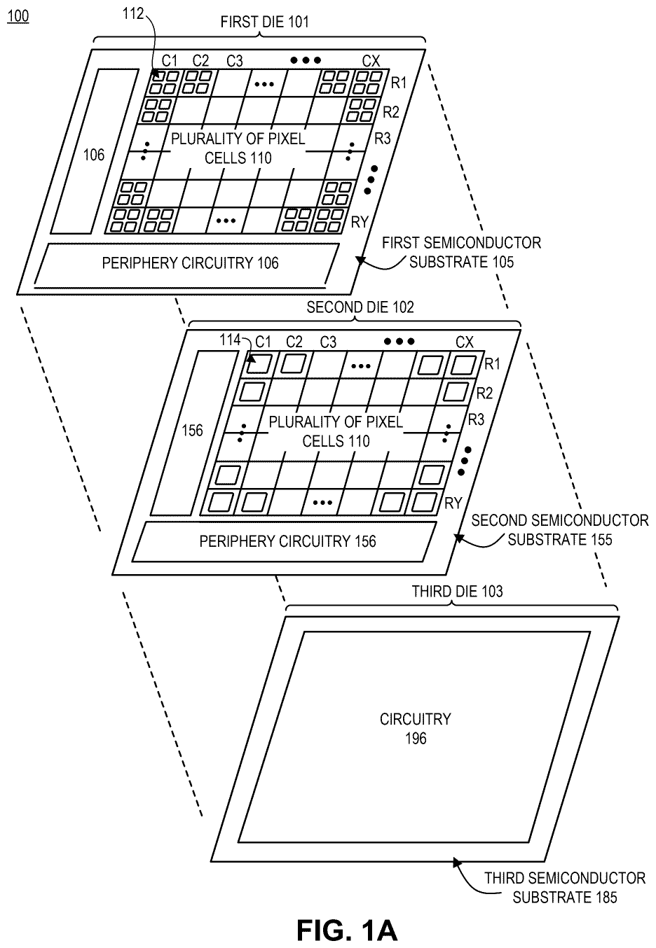

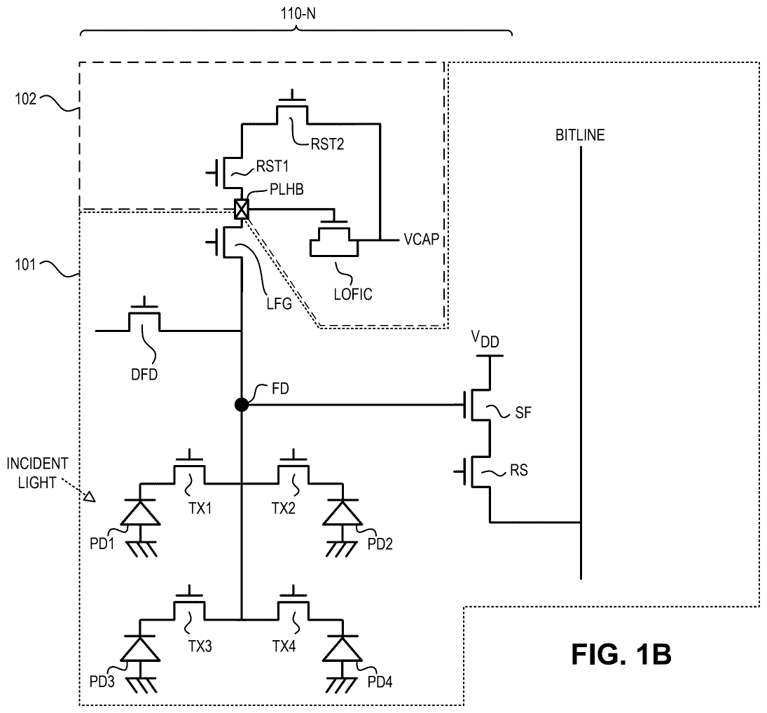

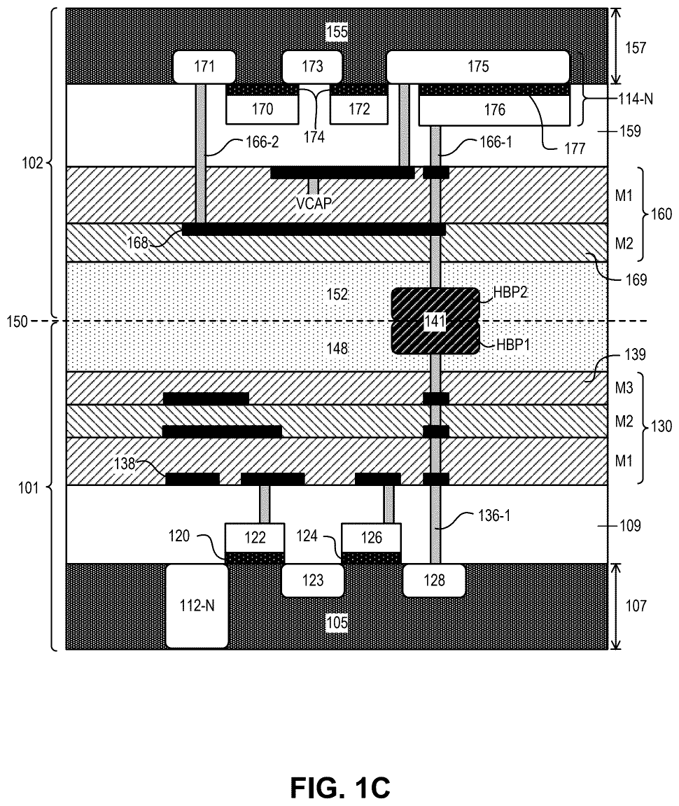

FIG. 1A illustrates an image sensor 100 with reduced hybrid bond coupling, in accordance with an embodiment of the disclosure. Image sensor 100 is a stacked image sensor and includes a first die 101, a second die 102, and, optionally, a third die 103. First die 101 includes a first semiconductor substrate 105, a plurality of photodiodes 112, and periphery circuitry 106. Second die 102 includes a plurality of lateral overflow integration capacitors (LOFICs) 114, a second semiconductor substrate 155, and periphery circuitry 156. Third die 103 includes a third semiconductor substrate 185 and circuitry 196. First die 101, second die 102, and third die 103 are stacked (e.g., second die 102 is disposed between first die 101 and third die 103) vertically in physical contact and electrically coupled together to form stacked image sensor 100.

It is appreciated that components included in first die 101 and second die 102 collectively form a plurality of pixel cells 110. In other words, plurality of pixel cells 110 is distributed across two or more dies included in image sensor 100 (e.g., at least first die 101 and second die 102). Plurality of pixel cells 110 are arranged in rows (e.g., R1, R2, R3, . . . , RY) and columns (e.g., C1, C2, C3, . . . , CX) to form a pixel cell array with each pixel cell including at least one photodiode included in plurality of photodiodes 112 of first die 101 and at least one LOFIC included in plurality of LOFICs 114 of second die 102. In some embodiments, plurality of LOFICs 114 may be arranged into rows and columns forming an array of LOFICs with each individual LOFIC position in alignment with each a corresponding pixel area of a pixel cell. In some embodiments, groups of photodiodes are included in a given pixel cell if they share a common color filter and/or share readout circuitry (see, e.g., FIG. 1B). Put another way, each pixel cell included in plurality of pixel cells 110 represents a repeat unit of image sensor 100. In the illustrated embodiment of FIG. 1A, each pixel cell includes a two-by-two array of photodiodes included in plurality of pixel cells 110 and one LOFIC included in plurality of LOFICs 114 (i.e., a four-to-one correspondence between photodiodes and LOFIC for a given pixel cell). However, in other embodiments, there may be a different number of photodiodes and/or LOFICs. In one embodiment, each pixel cell included in plurality of pixel cells 110 may include exactly one photodiode, two photodiodes, four photodiodes, eight photodiodes, sixteen photodiodes, or any other number of photodiodes included in plurality of photodiodes 112. In the illustrated embodiment, there is a greater than one-to-one correspondence between photodiodes and LOFICs for a given pixel cell included in plurality of pixel cells 110. However, it is appreciated that in other embodiments a different correspondence between photodiodes and LOFICs may be utilized (e.g., a one-to-one correspondence between photodiodes and LOFICs for a given pixel cell included in plurality of pixel cells 110). In some embodiments components of a given pixel cell are vertically stacked (e.g., to facilitate electrical coupling between components of a given pixel cell that are distributed across two or more dies with reduced noise, separation distance, improved performance, and the like). In the illustrated embodiment, photodiodes and LOFICs for a given pixel cell vertically overlap (e.g., a photodiode included in plurality of photodiodes 112 and a respective LOFIC included in plurality of LOFICs 114 included in the given pixel cell vertically overlap one another). For example, in one embodiment, one or more of each photodiode included in plurality of photodiodes 112 associated with row “R1” and column “C1” is disposed within first die 101 to vertically overlap with one corresponding LOFIC included in plurality of LOFICs 114 associated with row “R1” and column “C1.”

It is appreciated that the term “semiconductor substrate” recited throughout the disclosure may correspond to a part of or an entirety of a semiconductor wafer (e.g., a silicon wafer). In some embodiments, the semiconductor substrate (e.g., first semiconductor substrate 105, second semiconductor substrate 155, and/or third semiconductor substrate 185) includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, first semiconductor substrate 105, the second semiconductor substrate 155, and/or third semiconductor substrate 185 may correspond to any semiconductor material or combination of materials that may be doped or otherwise configured to facilitate the formation of an integrated circuit (e.g., forming individual circuitry components such as source/drain regions of transistors, memory elements, photodiodes, or the like). For example, first semiconductor substrate 105 may correspond to one or more epitaxial layers (e.g., P or N doped silicon) formed on a carrier wafer. In such an embodiment, plurality of photodiodes 112 may be formed in the one or more epitaxial layers corresponding to first semiconductor substrate 105 while the carrier wafer may be removed or otherwise thinned during fabrication to form first die 101 and may be subsequently stacked and interconnected with second die 102 and/or third die 103. In some embodiments, the first semiconductor substrate 105, second semiconductor substrate 155, and/or third semiconductor substrate 185 may be formed of the same or different materials. It is further appreciated that the term “die” or “chip” recited throughout the disclosure includes a semiconductor substrate and components disposed in or on the semiconductor substrate (see, e.g., FIG. 1C). In the illustrated embodiment of FIG. 1A, first die 101 includes first semiconductor substrate 105, periphery circuitry 106, and a portion of plurality of pixel cells 110 (e.g., plurality of photodiodes 112). Additionally, it is appreciated that the view presented in FIG. 1A may omit certain elements of image sensor 100 to avoid obscuring details of the disclosure. In other words, not all elements of image sensor 100 may be labeled, illustrated, or otherwise shown within FIG. 1A or other figures throughout the disclosure. It is further appreciated that in some embodiments, image sensor 100 may not necessarily include all elements shown.

In the illustrated embodiment of FIG. 1A, plurality of photodiodes 112 include photodiode doped regions disposed within first semiconductor substrate 105 having a conductivity type different from first semiconductor substrate 105. For example, photodiode doped regions of plurality of photodiodes 112 may correspond to n-doped regions disposed within a p-type semiconductor substrate. More generally, the term “photodiode doped region” may correspond to a region within the semiconductor substrate that has been doped, for example by ion implantation, to have an opposite charge carrier type (i.e., conductivity type) relative to the majority charge carrier type of the semiconductor substrate such that an outer perimeter of each individual photodiode doped region forms a PN junction or a PIN junction of a photodiode. The plurality of photodiodes 112 are capable of photogenerating image charge in response to incident light. Plurality of LOFICs 114 correspond to capacitors (e.g., metal-oxide semiconductor capacitor, metal-insulator-metal capacitor, or the like) formed in or on second semiconductor substrate 155 coupled to store excess image charge photogenerated by plurality of photodiodes 112. More generally, plurality of LOFICs 114 provides increased full well capacity for plurality of pixel cells 110 to facilitate increased dynamic range (e.g., during bright lighting conditions, excess image charge photogenerated by plurality of photodiodes 112 may be stored correspondingly in plurality of LOFICs 114).

As illustrated in FIG. 1A, first die 101 and second die 102 include various analog and/or digital support circuitry for image sensor 100, respectively corresponding to periphery circuitry 106 and periphery circuitry 156. In some embodiments, support circuitry that may be included in periphery circuitry 106 and/or periphery circuitry 156 may include, but is not limited to, row and column decoders and drivers, analog signal processing chains, digital imaging processing blocks, memory, timing and control circuits, input/output interfaces, a vertical scanner, sample and hold circuitry, amplifiers, analog-to-digital converter circuitry, and any other embodiments of logic and/or circuitry that is appropriate for the function of image sensor 100. In the illustrated embodiment, optional third die 103 includes circuitry 196 disposed in or on third semiconductor substrate 185. Circuitry 196 may include analog to digital circuitry, signal processing circuitry, and other circuitry to facilitate imaging, signal processing, or otherwise facilitate operation of image sensor 100. In the same or other embodiments, circuitry 196 may correspond to or otherwise include an application specific integrated circuit or a general-purpose microprocessor, or the like.

FIG. 1B illustrates an example circuit diagram representative of pixel cell 110-N included in plurality of pixel cells 110 of image sensor 100 of FIG. 1A, in accordance with an embodiment of the disclosure. It is appreciated that pixel cell 110-N may be representative of each pixel cell included in plurality of pixel cells 110. In other words, additional instances of pixel cell 110-N may collectively form plurality of pixel cells 110. Pixel cell 110-N includes one or more photodiodes (e.g., PD1, PD2, PD3, PD4) included in plurality of photodiodes 112, a LOFIC included in plurality of LOFICs 114, one or more transfer transistors (e.g., TX1, TX2, TX3, and TX4) included in a plurality of transfer transistors, a floating diffusion FD, a dual floating diffusion transistor DFD, a low conversion gain transistor LFG, a source-follower transistor SF, a row select transistor RS, a first reset transistor RST1, and a second reset transistor RST2.

It is appreciated that components of pixel cell 110-N are distributed across first die 101 and second die 102. Specifically, photodiodes PD1, PD2, PD3, and PD4, transfer transistors TX1, TX2, TX3, and TX4, floating diffusion FD, dual floating diffusion transistor DFD, low conversion gain transistor LFG, source-follower transistor SF, and row select transistor RS are each disposed or otherwise included in first die 101 while LOFIC, first reset transistor RST1, and second reset transistor RST2 are disposed or otherwise included in second die 102. The illustrated view also shows a bitline disposed or otherwise included in first die 101. A bonding connection PLHB corresponding to an active bonding connection or a first bonding connection provides an electrical interconnection between first die 101 and second die 102 for pixel cell 110-N. In some embodiments, a through-silicon via may be used to provide an electrical connection between first die 101 and third die 103. It is appreciated that in the illustrated embodiment, bonding connection PLHB corresponds to an interconnection formed via hybrid bond technology and thus may be referred to as a pixel cell level hybrid bond.

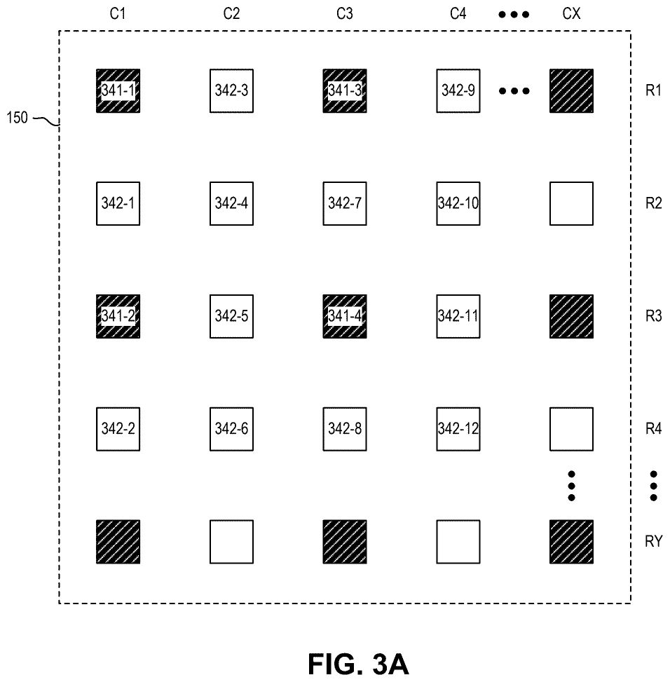

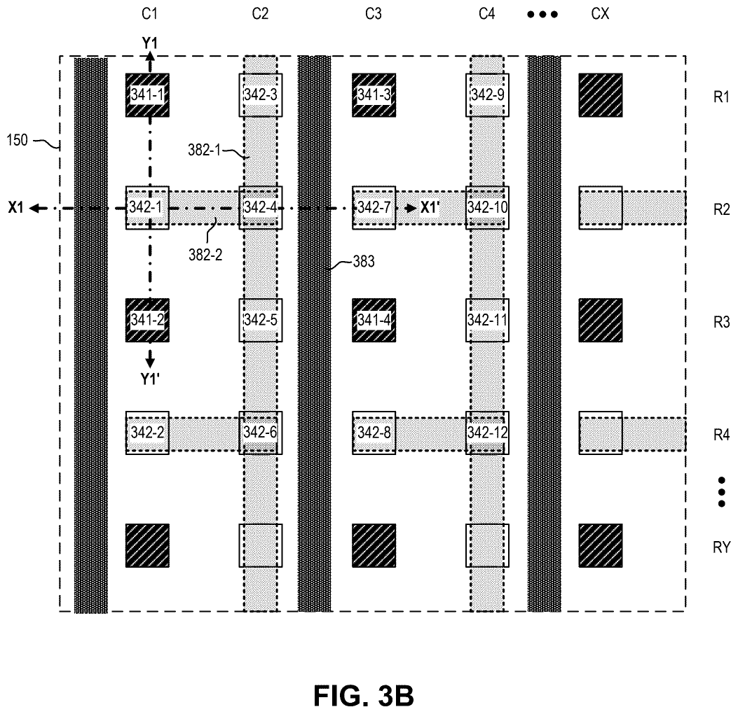

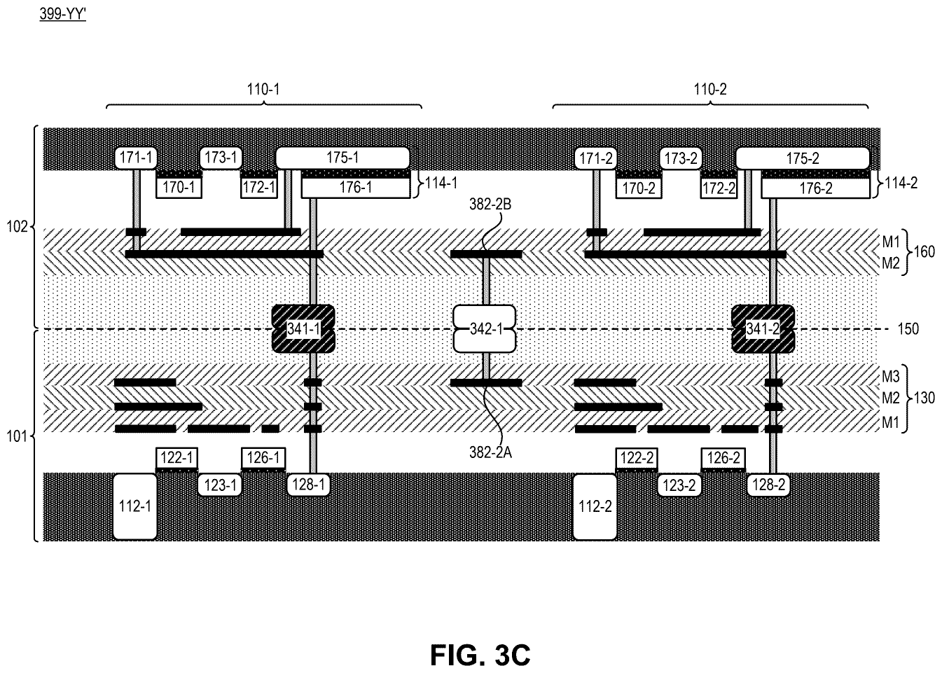

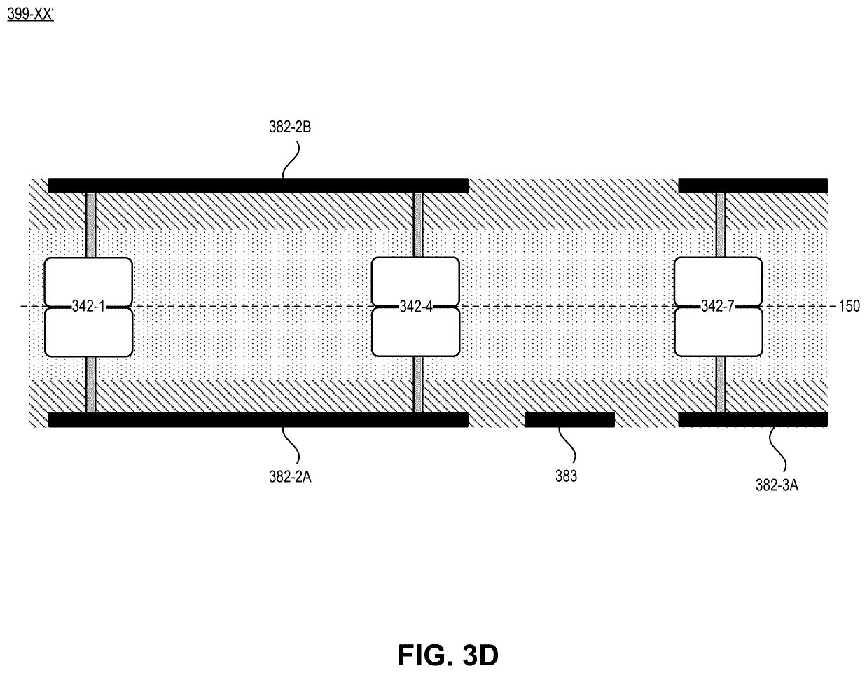

The specific arrangement and distribution of components of pixel cell 110-N facilitates reduced signal crosstalk between adjacent pixel cells included in plurality of pixel cells 110. For example, in the illustrated embodiment, pixel cell 110-N is capable of, but not limited to, operating with an individual bonding connection PLHB between first die 101 and second die 102, which enables reduced interconnection density for image sensor 100. A portion of readout circuitry (e.g., first reset transistor RST1 and second reset transistor RST2) for pixel cell 110-N is offloaded to second die 102 such that the LOFIC included in pixel cell 110-N may be directly connected to bonding connection PLHB. In some embodiments, first reset transistor RST1 is also directly coupled to bonding connection PLHB. In other words, in some embodiments there is no intervening transistor between a source/drain of first rest transistor RST1 and bonding connection PLHB and similarly no intervening transistor between an electrode of the LOFIC and the bonding connection PLHB. By offloading part of the readout circuitry for pixel cell 110-N, photodiode fill factor within first die 101 may be increased while still increasing full well capacity of pixel cell 110-N with the LOFIC. In some embodiments, the LOFIC of pixel cell 110-N is directly coupled to bonding connection PLHB. The direct connection between bonding connection PLHB and the LOFIC of pixel cell 110-N means there are no intervening transistors disposed therebetween (e.g., one or more vias or metal wires couple a contact of the LOFIC directly to the bonding connection PLHB such that there is always a continuous conductive pathway between the contact of the LOFIC and the bonding connection PLHB). In some embodiments, the direct connection between the LOFIC and the bonding connection PLHB for the pixel cell 110-N enables readout components to be arranged for reduced crosstalk between adjacent pixel cells. For example, in some embodiments, dummy interconnections (see, e.g., FIG. 3A-3D) are disposed between active interconnections (e.g., bonding connections coupled to a LOFIC in second die 102 such as bonding connection PLHB) which shield the active bonding connections to further reduce crosstalk between adjacent pixel cells.

As illustrated in FIG. 1B, transfer transistor TX1 is coupled between photodiode PD1 and floating diffusion FD, transfer transistor TX2 is coupled between photodiode PD2 and floating diffusion FD, transfer transistor TX3 is coupled between photodiode PD3 and floating diffusion FD, and transfer transistor TX4 is coupled between photodiode PD4 and floating diffusion FD. In some embodiments, low conversion gain transistor LFG and dual floating diffusion transistor DFD of pixel cell 110-N are coupled in parallel between bonding connection PLHB and floating diffusion FD. In the same or other embodiments, second reset transistor RST2 is coupled between first reset transistor RST1 and a voltage source VCAP. A first electrode of the LOFIC included in pixel cell 110-N is coupled to a voltage source VCAP while a second electrode of the LOFIC included in pixel cell 110-N is coupled to bonding connection PLHB. A source/drain of first reset transistor RST1 is coupled to bonding connection PLHB. In the same or other embodiments, a gate of source-follower transistor SF is coupled to floating diffusion FD. In some embodiments, row select transistor RS is coupled to source-follower transistor SF. In the same or other embodiments, dual floating diffusion transistor DFD is coupled between floating diffusion FD and a second floating diffusion FD2 or capacitor (not illustrated). In the same or other embodiments, source-follower transistor SF and row select transistor RS are coupled between a power line VDD and the bitline. In some embodiments, a through-silicon via that extends between first die 101 and third die 103 may be configured to provide an interconnection between the bitline of first die 101 and logic circuitry 196 of third die 103. In other embodiments, a pixel-level hybrid bonding pad may be used to provide an interconnection that routes the bitline of first die 101 to periphery circuitry 156 on second die 102 and/or logic circuitry 196. It is appreciated that the example circuit diagram is one possible implementation and that in some embodiments, dual floating diffusion transistor DFD of pixel cell 110-N may be omitted (e.g., depending on the high dynamic range implementation of the image sensor 100, there may be one or more transistors coupled between the LOFIC of the second die 102 and the floating diffusion FD of the first die 101. In some embodiments, the dual floating diffusion transistor DFD and the low conversion gain transistor LFG are coupled in series.

In the illustrated embodiment, photodiodes PD1, PD2, PD3, and/or PD4 are configured to photogenerate image charge in response to incident light. Floating diffusion FD is selectively coupled to receive the image charge from photodiodes PD1, PD2, PD3, and/or PD4 respectively through transfer transistors TX1, TX2, TX3, and/or TX4. As illustrated, photodiodes PD1, PD2, PD3, and PD4 share floating diffusion FD. However, in other embodiments, each photodiode included in pixel cell 110-N may be coupled to a different respective floating diffusion through a respective transfer transistor. Transfer transistors TX1, TX2, TX3, and/or TX4 are respectively coupled to be controlled in response to a control signal applied to a gate electrode of each respective transfer transistor. In some embodiments, excess image charge (e.g., photogenerated in response to bright lighting conditions) is configured to overflow from one or more of photodiodes PD1, PD2, PD3, and/or PD4 to floating diffusion FD through a respective one of transfer transistors TX1, TX2, TX3, and/or TX4. For example, during an idle period or integration period excess image charge is configured to overflow from photodiode PD1 to floating diffusion FD through transfer transistor TX1 when photodiode PD1 saturates, to a second floating diffusion or a second capacitor (not illustrated) coupled between dual floating diffusion DFD and floating diffusion FD (e.g., an additional floating diffusion) when floating diffusion FD is also full, and then to the LOFIC through low conversion gain transistor LFG when the additional floating diffusion is also full. In such a manner dynamic range of the image sensor may be increased through the use of floating diffusion FD, the additional floating diffusion, and the LOFIC. In some embodiments the additional floating diffusion may be omitted. Pixel cell 110-N is further configured to output an image signal in response to a row select control signal applied to a gate of row select transistor RS and the amount of charge (e.g., image charge photogenerated by the photodiodes PD1, PD2, PD3, and/or PD4 which may be stored at floating diffusion FD, the additional floating diffusion, and/or the LOFIC) at the gate of source-follower transistor SF. The image signal is representative of the image charge photogenerated and may be passed to circuitry 196 included in third die 103 for further processing (e.g., to generate an image representative of an external scene).

In some embodiments, voltage source VCAP is coupled to provide a bias voltage to the drain second reset transistor RST2 and a first electrode of the LOFIC. The second electrode of the LOFIC is coupled to the source of the first reset transistor RST1 and the drain of low conversion gain transistor LFG (e.g., through direct bonding connection PLHB). The first reset transistor RST1 and the second reset transistor RST2 are configured to be controlled in response to a respective control signal applied to corresponding gate electrodes. In some embodiments, the first and second electrodes of the LOFIC are both locally short circuited together enabling zero-biasing across the LOFIC and coupled to voltage source VCAP through first reset transistor RST1 and second reset transistor RST2, which shortens needed discharge time for the LOFIC. It is appreciated that in some embodiments, voltage source VCAP may also be utilized to reset or otherwise configure the LOFIC, the additional floating diffusion, floating diffusion FD, and photodiodes PD1, PD2, PD3, and/or PD4 to a pre-determined voltage. In some embodiments, VCAP is a variable voltage source (e.g., capable of providing at least a first voltage bias and a second voltage bias different from the first voltage bias). In such a manner bonding connection PLHB provides between first die 101 and second die 102 such that first reset transistor RST1 and/or second reset transistor RST2 may be selectively coupled to photodiodes PD1, PD2, PD3, PD4, floating diffusion FD, and the additional floating diffusion through transfer transistors TX1, TX2, TX3, TX4, low conversion gain transistor LFG, and dual floating diffusion transistor DFD as appropriate to reset photodiodes PD1, PD2, PD3, PD4, floating diffusion FD, and/or the additional floating diffusion.

FIG. 1C illustrates a cross-sectional view of pixel cell 110-N included in plurality of pixel cells 110 of image sensor 100 illustrated in FIG. 1A and represented by the example circuit diagram illustrated in FIG. 1B, in accordance with an embodiment of the disclosure. The illustrated cross-sectional view shows first die 101 vertically stacked with second die 102 to form bonding interface 150. Bonding interface 150 corresponds to where first die 101 is adhered to and physically in contact with second die 102. First die 101 includes first semiconductor substrate 105, interlayer dielectric 109, photodiode 112-N, interlayer dielectric 109, gate dielectric 120, gate electrode 122, floating diffusion 123, gate dielectric 124, gate electrode 126, source/drain region 128, plurality of metallization layers 130, plurality of vias 136, plurality of metal wires 138, intermetal dielectric 139, dielectric layer 148, and a portion HBP1 of active bonding connection 141. Second die 102 includes LOFIC 114-N, a portion HBP2 of active bonding connection 141, dielectric layer 152, second semiconductor substrate 155, interlayer dielectric 159, plurality of metallization layers 160, plurality of vias 166, plurality of metal wires 168, intermetal dielectric 169, gate electrode 170, gate electrode 172, source/drain region 171, source/drain region 173, gate dielectrics 174, first electrode 175, second electrode 176, and dielectric 177.

Photodiode 112-N is representative of any photodiode included in the example circuit diagram of pixel cell 110-N illustrated in FIG. 1B (e.g., one of photodiodes PD1, PD2, PD3, or PD4) and/or any one of plurality of photodiodes 112 illustrated in FIG. 1A. Gate dielectric 120 and gate electrode 122 form, at least in part, a transfer transistor coupled between photodiode 112-N and floating diffusion 123 and thus are representative of any of transfer transistors TX1, TX2, TX3, or TX4 included in the example circuit diagram of pixel cell 110-N illustrated in FIG. 1B. Floating diffusion 123 in the first semiconductor substrate 105 is representative of floating diffusion FD included in the example circuit diagram of pixel cell 110-N. Gate dielectric 124 and gate electrode 126 form, at least in part, a low conversion gain transistor coupled between floating diffusion 123 and LOFIC 114-N and thus are representative of low conversion gain transistor LFG included in the example circuit diagram of pixel cell 110-N illustrated in FIG. 1B. It is appreciated that source/drain region 128 in first semiconductor substrate 105 corresponds to a source or drain electrode for the low conversion gain transistor LFG. Active bonding connection 141 is representative of bonding connection PLHB in the example circuit diagram of pixel cell 110N illustrated in FIG. 1B.

First electrode 175 (e.g., a doped impurity region in the second semiconductor substrate 155), second electrode 176 (e.g., polysilicon electrode formed on semiconductor substrate 155), and dielectric 177 (e.g., insulation material) form LOFIC 114-N, which is representative of the LOFIC included in the circuit diagram of pixel cell 110-N illustrated in FIG. 1B and/or any one of plurality of LOFICs 114 illustrated in FIG. 1A. Gate electrode 170 and the underlying one of gate dielectrics 174 form, at least in part, a first reset transistor and thus are representative of first reset transistor RST1 included in the example circuit diagram of pixel cell 110-N illustrated in FIG. 1B. Gate electrode 172 and the underlying one of gate dielectrics 174 form, at least in part, a second reset transistor and thus are representative of second reset transistor RST2 included in the example circuit diagram of pixel cell 110-N illustrated in FIG. 1B. It is appreciated that source/drain region 171 disposed in second semiconductor substrate 155 corresponds to an electrode (e.g., source or drain) for first reset transistor RST1. In some embodiments, a source/drain of first reset transistor RST1 (e.g., source/drain 171) is coupled to active bonding connection 141 (e.g., coupled to portion or bonding pad HBP2) through via 166-2 and corresponding metal wire 168. In some embodiments, source/drain region 173 disposed in second semiconductor substrate 155 corresponds to a shared electrode (e.g., source or drain) for first reset transistor RST1 and second reset transistor RST2.

In the illustrated embodiment of FIG. 1C, photodiode 112-N, floating diffusion 123, source/drain region 128, source/drain region 171, source/drain region 173, and/or first electrode 175 include or otherwise correspond to a doped region having a different or opposite conductivity type relative to the conductivity type of the semiconductor substrate or surrounding medium the components are disposed therein (e.g., n-doped regions disposed within or surrounded by a p-doped semiconductor material or substrate). In the same or other embodiments, gate electrode 122, gate electrode 126, gate electrode 170, gate electrode 172, and second electrode 176 may include or otherwise correspond to a metal material (e.g., Au, Ag, Al, Cu, Ta, Ti, Nb), polycrystalline silicon (extrinsic or intrinsic), a silicide material, metal composites (e.g., WN, TiN, TaN, other metal nitrides, RuOₓ, or other metal oxide electrode materials), other conductive materials with the appropriate conductivity and work function, or combinations thereof. In some embodiments, gate dielectric 120, gate dielectric 124, gate dielectrics 174, include one or more insulating materials (e.g., silicon dioxide, hafnium dioxide, or other gate dielectric materials known by one of ordinary skill in the art). In the same or other embodiments, interlayer dielectric 109, intermetal dielectric 139, dielectric layer 148, dielectric layer 152, interlayer dielectric 159, and intermetal dielectric 169 form an insulating matrix or medium, each of which may include one or more dielectric or insulating materials such as silicon dioxide, organosilicate glass such as SiCOH, porous SiCOH, other insulating materials, or combinations thereof that collectively form an insulating matrix.

Disposed within the insulating matrix are one or more metallization layers (e.g., M1, M2, M3), dielectrics 148 and 152, lines or wires (e.g., plurality of metal wires 138 and 168), and/or vias (e.g., plurality of vias 136 and 166) that provide, inter alia, one or more interconnections (e.g., active bonding connection 141) spanning between first semiconductor substrate 105 and second semiconductor substrate 155, routing between components within first die 101, routing between components within second die 102, and/or routing between components between first die 101 and second die 102. It is appreciated that plurality of metal wires 138, plurality of metal wires 168, plurality of vias 136, and plurality of vias 166 may include or otherwise correspond to a conductive material such as Au, Al, Cu, W, one or more alloys such as an aluminum alloy, other conductive materials, or combinations thereof. In some embodiments, active bonding connection 141 includes Cu, Au, other metals, or combinations thereof.

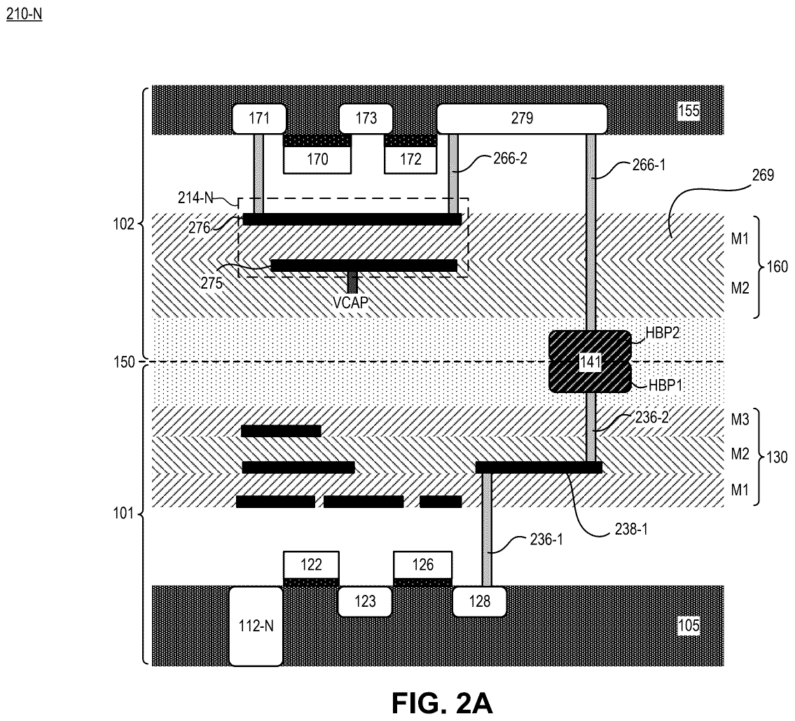

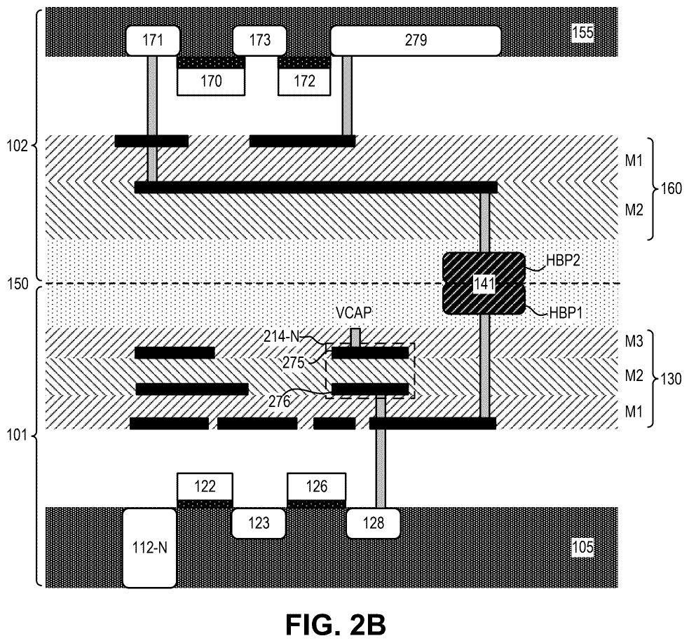

In the illustrated embodiment, LOFIC 114-N is a metal-oxide-semiconductor capacitor (e.g., MOSCAP), where first electrode 175 corresponds to the “semiconductor” (e.g., a doped silicon region disposed within second semiconductor substrate 155), second electrode 176 corresponds to the “metal” (e.g., Au, Ag, Al, Cu, Ta, Ti, Nb, polycrystalline silicon (extrinsic or intrinsic), a silicide material, metal composites such as WN, TiN, TaN, other metal nitrides, RuOₓ, or other metal oxide electrode materials, other conductive materials with the appropriate conductivity and work function, or combinations thereof), and dielectric 177 corresponds to the “dielectric” (e.g., silicon dioxide). However, in other embodiments, LOFIC 114 may correspond to a metal-insulator-metal capacitor (see, e.g., FIG. 2A-2B), a metal-oxide-metal interdigitated capacitor, or the like. In one embodiment, dielectric 177 is disposed between first electrode 175 and second electrode 176. In the illustrated embodiment, first electrode is coupled to voltage source VCAP (e.g., through one or more of plurality of vias 166 in interlayer dielectric 159 and one or more plurality of metal wires 168 in intermetal dielectric 169) while second electrode 176 is coupled to active bonding connection 141 (e.g., through a vertical interconnect structure such as via 166-1).

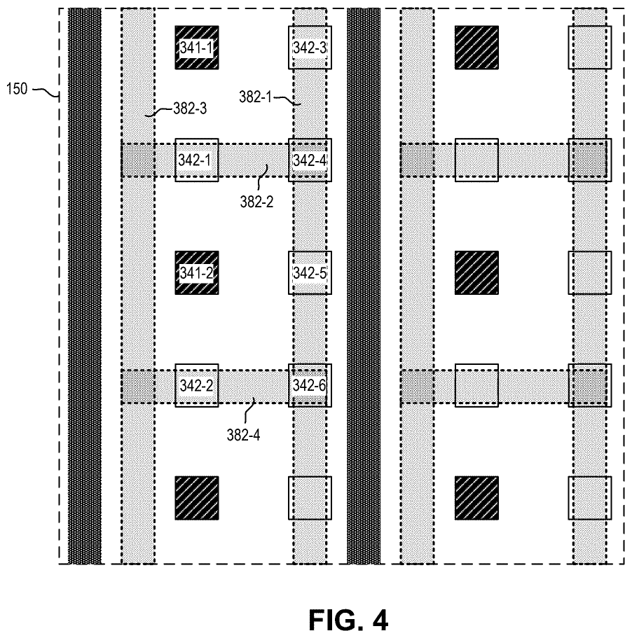

As illustrated in FIG. 1C, LOFIC 114-N has a direct connection to active bonding connection 141 (e.g., through via 166-1 coupled between second electrode 176 and portion or bonding pad HBP2) active bonding connection 141). In other words, there are no intervening switches (e.g., transistors) that could inhibit the electrical connection between active bonding connection 141 and second electrode 176 of LOFIC 114-N. By having a direct connection, LOFIC 114-N may subsequently be actively or passively shielded in some embodiments (see, e.g., FIG. 3A-4) to further mitigate coupling between adjacent active bonding connections (i.e., hybrid bond coupling). This advantage may also be extended between active bonding connection 141 and source/drain region 128 of the LCG transistor such that there is a direct connection (e.g., provided by via 136-1) between active bonding connection 141 and source/drain region 128. As discussed previously, the configuration of the LOFIC 114-N relative to other components included in the pixel cell 110-N (e.g., the specific configuration and distribution between first die 101 and second die 102 of components included in pixel cell 110-N) facilitates operation of image sensor 100 with a reduced density of pixel cell level hybrid bonds (e.g., the number of interconnects per pixel cell may be reduced) which increases separation distance of active bonding connections and reduces hybrid bonding coupling. The configuration of components also enables first semiconductor substrate 105 and second semiconductor substrate 155 to have different thickness. More specifically, a first thickness 107 of first semiconductor substrate 105 included in first die 101 is greater than a second thickness 157 of second semiconductor substrate 155 included in second die 102. In such a manner a total thickness of image sensor 100 may be reduced and less material may be utilized when forming second die 102 for reduced manufacturing costs.

FIG. 2A illustrates a cross-sectional view of a pixel cell 210-N with a metal-insulator-metal LOFIC 214-N, in accordance with an embodiment of the disclosure. Pixel cell 210-N is one possible implementation of a pixel cell included in plurality of pixel cells 110 illustrated in FIG. 1A-1B. Indeed, pixel cell 210-N includes many of the same or similar features to pixel cell 110-N illustrated in FIG. 1C. One difference is LOFIC 214-N is a metal-insulator-metal type capacitor while LOFIC 114-N is a metal-oxide-semiconductor capacitor. Accordingly, pixel cell 210-N shows an example implantation of a different capacitor type for a plurality of LOFICs, in accordance with an embodiment of the disclosure. In the illustrated embodiment of FIG. 2A, LOFIC 214-N includes first electrode 275 coupled to voltage source VCAP, second electrode 276 directly connected to portion or bonding pad HBP2 of active bonding connection 141 (e.g., through via 266-1, via 266-2, and electrode 279), and an insulator disposed between first electrode 275 and second electrode 276 (e.g., portion of insulating material 269 disposed between first electrode 275 and second electrode 276). In some embodiments, electrode 279 corresponds to a doped region within second semiconductor substrate 155. As illustrated, LOFIC 214-N is formed within plurality of metallization layers 160, which allows for additional control over LOFIC design. In the illustrated embodiment, LOFIC 214-N formed in second die 102 vertically overlaps with photodiode 112-N (photodiode doped region of photodiode 112-N) formed in first die 101. Another difference between pixel cell 110-N of FIG. 1C and pixel cell 210-N of FIG. 2A is the routing between source/drain region 128 and active bonding connection 141 includes via 236-1, via 236-2, and metal wire 238-1. In other words, additional metal wires or vias within either or both of metallization layers 130 and 160 may be utilized to provide routing between source/drain region 128 and active bonding connection 141 (e.g., portion or bonding pad HBP1) and/or LOFIC 214-N and active bonding connection 141.

FIG. 2B illustrates an alternative configuration of pixel cell 210-N illustrated in FIG. 2A, in accordance with an embodiment of the disclosure. Specifically, pixel cell 210-N illustrated in FIG. 2B shows that LOFIC 214-N may be disposed within first die 101 (e.g., within a corresponding region of pixel cell 210-N included in first die 101) whereas FIG. 2A shows LOFIC 214-N may be located within second die 102. In the illustrated embodiment, LOFIC 214-N may be disposed in metallization layers 130. However, it is appreciated that even with LOFIC 214-N disposed in first die 101, a direct bonding connection between LOFIC 214-N and active bonding connection 141 (e.g., portion or bonding pad HBP1) is provided to reduce hybrid bond coupling between adjacent active bonding connections. It is appreciated that in some embodiments an additional pixel level hybrid bond (i.e., interconnection between first die 101 and second die 102) may also be utilized to couple LOFIC 214-N to voltage source VCAP.

FIG. 3A illustrates a plan view of bonding interface 150 formed between first die 101 and second die 102, in accordance with an embodiment of the disclosure. Specifically, FIG. 3A illustrates a plurality of active bonding connections (e.g., 341-1, 341-2, 341-3, 314-4, etc.) interspersed within a plurality of dummy bonding connections 342 (e.g., 342-1, 342-2, 342-3, 342-4, 342-5, 342-6, 342-7, 342-8, 342-9, 342-10, 342-11, 342-12, etc.) collectively arranged in rows (e.g., R1, R2, R3, R4, . . . , RY) and columns (e.g., C1, C2, C3, C4, . . . . CX) to form a bonding connection array. Each of the plurality of active bonding connections 341 may correspond to an instance of active bonding connection 141 illustrated in FIG. 1C-2B that is coupled to a LOFIC, in accordance with embodiments of the disclosure. In other words, an “active” bonding connection included in plurality of active bonding connections 341 corresponds to a bonding connection formed at bonding interface 150 that may be directly coupled to a corresponding instance of a LOFIC included in plurality of LOFICs 114 illustrated in FIG. 1A of image sensor 100. In such an embodiment, each pixel cell included in plurality of pixel cells 110 of image sensor 100 includes a corresponding instance of a LOFIC included in plurality of LOFICs 114. In the same or other embodiment, the corresponding instance of the LOFIC for each of plurality of pixel cells 110 is directly coupled to a respective bonding connection (e.g., 341-1, 341-2, 341-3, 341-4, etc.) included in plurality of active bonding connections 341 such that there is exactly a one-to-one correspondence between plurality of active bonding connections 341 and plurality of pixel cells 110. However, in other embodiments, there may be a greater than one-to-one correspondence between plurality of active bonding connections 341 and plurality of pixel cells 110. In some embodiments, there is a one-to-one correspondence between plurality of active bonding connections 341 and plurality of pixel cells 110 and a greater than one-to-one correspondence between plurality of dummy bonding connections 342 and plurality of pixel cells 110. In the same or other embodiments, there is a greater than one-to-one correspondence between plurality of dummy bonding connections 342 and plurality of active bonding connections 341.

The plurality of dummy bonding connections 342, which in some embodiments may be coupled to one or more metal wires (see, e.g., FIG. 3C), may function to reduce hybrid bonding coupling between plurality of active bonding connections 341. In the illustrated embodiment of FIG. 3A, each active bonding connection included in plurality of bonding connections 341 is separated and distanced from a nearest other active bonding connection (i.e., adjacent active bonding connection) included in plurality of active bonding connections 341 by a dummy bonding connection included in plurality of dummy bonding connections 342. For example, dummy bonding connection 342-3 is laterally disposed between active bonding connection 341-1 and active bonding connection 341-3. In some embodiments, even diagonally adjacent active bonding connections are separated by a dummy bonding connection. For example, dummy bonding connection 342-4 is disposed between active bonding connection 341-1 and active bonding connection 341-4. In some embodiments, individual bonding connections included in plurality of active bonding connections 341 are at least partially surrounded by and adjacent to plurality of dummy bonding connections 342. It is appreciated that the term, “partially surrounded” indicates that a given cell included in the bonding connection array associated with an active bonding connection included in plurality of bonding connections 341 is adjacent to three or more cells associated with a respective dummy bonding connection included in plurality of dummy bonding connections 342. For example, active bonding connection 341-1 is adjacent to dummy bonding connections 342-1, 342-3, and 342-4 and thus at least partially surrounded by dummy bonding connections 342. In the same or other embodiments, each active bonding connection included in plurality of active bonding connection 341 is completely laterally surrounded by a group of dummy bonding connections included in plurality of dummy bonding connections 342. For example, active bonding connection 341-4 is surrounded by dummy bonding connections 342-4, 342-5, 342-6, 342-7, 342-8, 342-10, 342-11, and 342-12.

In some embodiments, the bonding connection array includes a first row (or column) pattern alternating between active bonding connections included in plurality of active bonding connections 341 and dummy bonding connections included in plurality of dummy bonding connections 342 adjacent to or separated by a second row (or column) pattern without active bonding connections included in plurality of active bonding connections 341 (e.g., only bonding connections included in the second row or column pattern correspond to dummy bonding connections included in plurality of dummy bonding connections 342). For example, column C1 alternates between an active bonding connection included in plurality of active bonding connections 341 and a dummy bonding connection included in plurality of dummy bonding connections 342 while the only bonding connections included in column C2 correspond to dummy bonding connections included in plurality of dummy bonding connections 342. In some embodiments, the bonding connection array alternates between the first row (or column) pattern and the second row (or column) pattern. Put in another way, columns (or rows) of the bonding connection array include a first column (e.g., C1) and a second column (e.g., C2) adjacent to the first column. The first column alternates between an active bonding connection included in plurality of active bonding connections 341 and a dummy bonding connection included in plurality of dummy bonding connections 342 while the second column does not include plurality of active bonding connections 341.

It is appreciated that the “shielding effect” provided by plurality of dummy bonding connections 342 may be extended depthwise into first die 101 and/or second die 102 by coupling plurality of dummy bonding connections 342 to one or more vias and or metal wires (see, e.g., FIG. 3B). In some embodiments, plurality of dummy bonding connections 342 is coupled to a reference voltage or a ground voltage to further mitigate coupling between adjacent interconnections formed by plurality of active bonding connections 342. In some embodiments, plurality of dummy bonding connections 342 is configured to be floating. It is appreciated that in some embodiments, a reference or ground voltage may provide reduced coupling relative to having plurality of dummy bonding connections 342 floating. However, it is appreciated that hybrid bond coupling may be reduced or otherwise improved by plurality of dummy bonding connection 342 (e.g., relative to not having plurality of dummy bonding connections 342).

FIG. 3B illustrates an expanded view of the plan view illustrated in FIG. 3B that further shows plurality of metal wires 382 coupled to plurality of dummy bonding connections 342 for image sensor 100, in accordance with an embodiment of the disclosure. It is appreciated that the plurality of metal wires 382 may be formed in one or more metallization layers included in first die 101 and/or second die 102 (e.g., metallization layers 130 and/or 160 formed in first die 101 and/or second die 102 illustrated in FIG. 1C and FIG. 3C) and through one or more vias included in a plurality of vias (e.g. plurality of vias 136 and/or 166 illustrated in FIG. 1C and FIG. 3C). In some embodiments, plurality of metal wires 382 may be disposed in a metallization layer closest to bonding interface 150 (e.g., M3 metallization layer of first die 101 and/or M2 metallization layer of second die 102 as illustrated in FIG. 1C and FIG. 3C). However, in other embodiments, plurality of metal wires 382 may also or alternatively be disposed in other metallization layers closer to a corresponding semiconductor substrate (e.g., M1 and/or M2 metallization layer of first die 101 and/or M1 metallization layer of second die 102 illustrated in FIG. 1C and FIG. 3C).

In the illustrated embodiment, each metal wire included in plurality of metal wires 382 is coupled to at least two adjacent dummy bonding connections included in plurality of dummy bonding connections 342 such that when viewed from a plan view (e.g., as illustrated in FIG. 3B), one or more of active bonding connections included in plurality of active bonding connections 341 is at least partially surrounded by plurality of metal wires 382. The term “partially surrounded” indicates at least two sides of a given active bonding connection included in plurality of active bonding connections 341 adjacent to plurality of metal wires 382 is continuously surrounded. In another embodiment, at greater than 25% of an outer perimeter of a given active bonding connection included in plurality of active bonding connections 341 is laterally surrounded by plurality of metal wires 382 when viewed from a plan view. In the same or another embodiment, greater than 30%, greater than 40%, greater than 50%, greater than 60%, greater than 70%, greater than 80%, or greater than 90% and up to 100% of an outer perimeter of a given active bonding connection included in plurality of active bonding connections 341 is laterally surrounded by plurality of metal wires 382. In one example, two sides of active bonding connection 341-1 are laterally surrounded by plurality of metal wires 382 (e.g., metal wires 382-1 and 382-2). In another example, three sides of active bonding connection 341-2 are laterally surrounded by plurality of metal wires 382.

As illustrated in FIG. 3B, metal wire 382-1 extends along a first direction (e.g., y-direction) while metal wire 382-1 extends along a second direction (e.g., x-direction) perpendicular to the first direction. In one embodiment, metal wire 382-1 is coupled to a column or row (e.g., second column C2) of plurality of dummy bonding connections 342 of the bonding connection array. In the same or other embodiments, one or more of plurality of metal wires 382 extends parallel to a column (or row) included in the bonding connection array. In the same or other embodiments, one or more of plurality of metal wires 382 extends perpendicular to a column (or row) included in the bonding connection array. For example, metal wire 382-1 extends in a direction that is parallel to a direction of column C2 of the bonding connection array while metal wire 382-2 extends in a direction that is parallel to a direction of row R2 of the bonding connection array. In the same or other embodiments, metal wire 382-1 is perpendicular to metal wire 382-2. In some embodiments, metal wire 382-1 is coupled to at least four dummy bonding connections (e.g., dummy bonding connections 342-3, 342-4, 342-5, and 352-6). In the illustrated embodiment, metal wire 382 is coupled to two dummy bonding connections (e.g., dummy bonding connections 342-1 and 342-2). It is appreciated that plurality of metal wires 382 may be configured to be floating or coupled to a reference voltage, a ground voltage (e.g. such that plurality of dummy bonding connections 342 is also coupled to a reference voltage or a ground voltage, or left floating) to shield adjacent active bonding connections included in plurality of active bonding connections 341 from hybrid bond coupling. In one embodiment, metal wire 382-3 is coupled to dummy bonding connection 342-3 such that metal wire 382-3 is further disposed between active bonding connection 341-1 and active bonding connection 341-3 when viewed from a plan view. In some embodiments, one or more of plurality of metal wires 382 is disposed parallel or adjacent to power line 383 (e.g., coupled to a power supply such as VDD as illustrated in FIG. 1B).

FIG. 3C illustrates a cross-sectional view 399-YY′ extending through bonding interface 150 along line Y1-Y1′ shown in FIG. 3B, in accordance with an embodiment of the disclosure. Cross-sectional view 399-YY′ illustrates two adjacent pixel cells 110-1 and 110-2, each of which are representative any one of pixel cell 110 illustrated in plurality of pixel cells 110 of FIG. 1A, pixel cell 110-N illustrated in FIGS. 1B-1C, and/or pixel cell 210-N illustrated in FIG. 2A-2B. Accordingly, each pixel cell illustrated in FIG. 3C includes a respective instance of a photodiode (e.g., 112-1, 112-2), gate electrode (e.g., 122-1, 122-2) of a transfer transistor, floating diffusion (e.g., 123-1, 123-2), gate electrode (e.g., 126-1, 126-2) and source/drain region (e.g., 128-1, 128-2) of a low conversion gain transistor, active bonding connection (e.g., 341-1, 342-2), gate electrodes (e.g., 170-1, 170-2, 172-1, 172-2) and source/drain regions (e.g., 171-1, 171-2, 173-1, 173-2) of first and second reset transistors, and first and second electrodes (e.g., 175-1, 175-2, 176-1, 176-2) of a LOFIC (e.g., 114-1, 114-2).

In the illustrated embodiment, LOFIC 114-1 is disposed within second die 102, is directly coupled to active bonding connection 341-1, and is further selectively coupled to floating diffusion 123-1 formed in first die 101 (e.g., through active bonding connection 341-1 and a low conversion gain transistor associated with gate electrode 126-1). In the illustrated embodiment, LOFIC 114-2 is disposed within second die 102, is directly coupled to active bonding connection 341-2, and is further selectively coupled to floating diffusion 123-2 formed in first die 101 (e.g., through active bonding connection 341-2 and a low conversion gain transistor associated with gate electrode 126-2). Dummy bonding connection 342-1 included in plurality of dummy bonding connections 342 is disposed between active bonding connection 341-1 (e.g., a first bonding connection) and active bonding connection 341-2 (e.g., a second bonding connection). In some embodiments, dummy bonding connection 342-1 is coupled to metal wire 382-2A and/or metal wire 382-2B, respectively disposed within one of the metallization layer 130 of first die 101 or metallization layer 160 of second die 102. In some embodiments, dummy bonding connection 342-1 and metal wires 382-2A and/or 382-2B reduce coupling between adjacent active bonding connections 341-1 and 341-2. In the same or other embodiments, dummy bonding connection 342-1, metal wire 382-2A, and/or metal wire 382-2 are coupled a reference voltage or a ground voltage, or in some instance configured to be floating.

FIG. 3D illustrates a cross-sectional view 399-XX′ extending through bonding interface 150 along line X1-X1′ shown in FIG. 3B, in accordance with an embodiment of the disclosure. As illustrated, dummy bonding connections 342-1 and 342-4 formed at bonding interface 150 are coupled together via metal wire 382-2A and/or 382-2B respectively disposed in first die 101 or second die 102. Cross-sectional view 399-XX′ further shows power line 383 disposed between metal wire 382-2A and a metal wire coupled to dummy bonding connective 324-7 formed at bonding interface 150.

FIG. 4 illustrates a modified arrangement of plurality of metal wires 382 relative to the expanded view shown in FIG. 3B for image sensor 100, in accordance with an embodiment of the disclosure. More specifically, FIG. 4 illustrates when viewed from a plan view, each active bonding connection (e.g., 341-2) included in plurality of active bonding connections 341 is completely or entirely laterally surrounded by plurality of metal wires 382 formed in the first die or the second die. For example, active bonding connection 341-2 is entirely surrounded, when viewed from the plan view illustrated in FIG. 4, collectively by metal wires 382-1, 382-2, 382-3, and 382-4. It is appreciated that plurality of metal wires 382 are coupled to one or more dummy bonding connections (e.g., 342-1, 342-2, 342-3, 342-4, 342-5, and 342-6 as illustrated) included in a plurality of dummy bonding connections 342 formed at bonding interface 150. Additionally, in some embodiments, plurality of dummy bonding connections 342 is coupled to a reference voltage, a ground voltage through one or more metal wires, or configured to be floating.

It is appreciated that embodiments of the disclosure illustrated in FIG. 1A-4 may be fabricated using conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. An image sensor, comprising:
a first die and a second die, wherein the first die and the second die are stacked to form a bonding interface disposed therebetween;
a plurality of pixel cells arranged in rows and columns to form a pixel cell array, wherein a first pixel cell included in the plurality of pixel cells includes:
a photodiode, disposed within the first die, configured to photogenerate image charge in response to incident light;
a floating diffusion, disposed within the first die, coupled to receive the image charge; and
a lateral overflow integration capacitor (LOFIC), disposed within the second die, selectively coupled to the floating diffusion through a first bonding connection formed at the bonding interface, and wherein the LOFIC is directly coupled to the first bonding connection.

2. The image sensor of claim 1, wherein the first pixel cell further comprises a low conversion gain (LFG) transistor and a dual floating diffusion (DFD) transistor disposed within the first die, wherein the LFG transistor and the DFD transistor are coupled in parallel between the first bonding connection and the floating diffusion.

3. The image sensor of claim 1, wherein the first pixel cell further comprises a first reset transistor and a second reset transistor disposed within the second die, wherein the second reset transistor is coupled between the LOFIC and the first reset transistor, and wherein the first resist transistor is coupled to the first bonding connection.

4. The image sensor of claim 1, wherein the first pixel cell further comprises
a source-follower transistor and a row select transistor disposed within the first die, wherein a gate of the source-follower transistor is coupled to the floating diffusion, wherein the row select transistor is coupled to the source-follower transistor, and wherein the source-follower transistor and the row select transistor are coupled between a power line and a bitline; and wherein the image sensor further includes:
a third die including logic circuitry, wherein the second die is disposed between the first die and the third die, and wherein the bitline of the first pixel cell is arranged on the first die and coupled to the logic circuitry on the third die.

5. The image sensor of claim 1, wherein the photodiode disposed within the first die is positioned to vertically overlap the LOFIC of the second die.

6. The image sensor of claim 1, further comprising a plurality of active bonding connections, including the first bonding connection, formed at the bonding interface, wherein each pixel cell included in the plurality of pixel cells includes a corresponding instance of the LOFIC, wherein the corresponding instance of the LOFIC for each of the plurality of pixel cells is directly coupled to a respective bonding connection included in the plurality of active bonding connections such that there is a one-to-one correspondence between the plurality of active bonding connections and the plurality of pixel cells.

7. The image sensor of claim 1, further comprising a plurality of dummy bonding connections formed at the bonding interface, wherein the plurality of dummy bonding connections is coupled to a reference voltage or a ground voltage.

8. The image sensor of claim 7, wherein the plurality of dummy bonding connections and the first bonding connection are collectively arranged in rows and columns to form a bonding connection array, wherein the first bonding connection is surrounded by and adjacent to the plurality of dummy bonding connections.

9. The image sensor of claim 8, further comprising a plurality of metal wires coupled to the plurality of dummy bonding connections, wherein each metal wire included in the plurality of metal wires is coupled to at least two adjacent dummy bonding connections included in the plurality of dummy bonding connections such that when viewed from a plan view, the first bonding connection is at least partially surrounded by the plurality of metal wires.

10. The image sensor of claim 7, wherein the plurality of pixel cells includes a second pixel cell adjacent to the first pixel cell, the second pixel cell comprising:
a second LOFIC disposed within the second die, the second LOFIC selectively coupled to a second floating diffusion disposed within the first die through a second bonding connection formed at the bonding interface, and wherein a first dummy connection included in the plurality of dummy bonding connections is disposed between the first bonding connection and the second bonding connection.

11. The image sensor of claim 10, further comprising a metal wire disposed in the first die or the second die, wherein the metal wire is coupled to the first dummy bonding connection such that the metal wire is disposed between the first bonding connection and the second bonding connection when viewed from a plan view.

12. The image sensor of claim 7, further comprising a plurality of active bonding connections, including the first bonding connection, formed at the bonding interface, wherein there is a greater than one-to-one correspondence between the plurality of dummy bonding connections and the plurality of active bonding connections.

13. The image sensor of claim 12, wherein the plurality of active bonding connections and the plurality of dummy bonding connections are collectively arranged in rows and columns to form a bonding connection array, wherein the columns of the bonding connection array include a first column and a second column adjacent to the first column, wherein the first column alternates between an active bonding connection included in the plurality of active bonding connections and a dummy bonding connection included in the plurality of dummy bonding connections, and wherein the second column does not include the plurality of active bonding connections.

14. The image sensor of claim 13, further comprising a metal wire disposed within the first die or the second die, wherein the metal wire is coupled to the plurality of dummy bonding connections included in the second column of the bonding connection array, and wherein the metal wire extends in a direction that is parallel to the second column.

15. The image sensor of claim 14, further comprising a power line disposed adjacent to the metal wire.

16. The image sensor of claim 1, wherein, when viewed from a plan view, the first bonding connection is completely surrounded by a plurality of metal wires formed in the first die or the second die, wherein the plurality of metal wires are coupled to one or more dummy bonding connections included in a plurality of dummy bonding connections formed at the bonding interface, and wherein the plurality of dummy bonding connections is floating or is coupled to one of a reference voltage or a ground voltage.

17. A pixel cell for an image sensor, the pixel cell comprising:
a photodiode, disposed within a first die, configured to photogenerate image charge in response to incident light;
a floating diffusion, disposed within the first die, coupled to receive the image charge;
a lateral overflow integration capacitor (LOFIC) disposed within the first die or a second die, wherein the first die and the second die are stacked to form a bonding interface disposed therebetween, and wherein the LOFIC is coupled to a bonding connection formed at the bonding interface;
a low conversion gain (LFG) transistor and a dual floating diffusion (DFD) transistor disposed within the first die, wherein the LFG transistor and the DFD transistor are coupled between the bonding connection and the floating diffusion, and wherein the LOFIC is selectively coupled to the floating diffusion through the LFG transistor; and
a reset transistor disposed within the second die, wherein the reset transistor is coupled to the LOFIC and the floating diffusion.

18. The pixel cell of claim 17, wherein the LOFIC is disposed within the second die, and wherein the LOFIC and the reset transistor are each directly coupled to the bonding connection.

19. The pixel cell of claim 17, wherein the reset transistor is a first reset transistor, wherein the pixel cell further comprises a second reset transistor disposed within the second die, and wherein the first reset transistor is coupled between and the LOFIC and the second reset transistor.

20. The pixel cell of claim 17, further comprising a plurality of dummy bonding connections formed at the bonding interface, wherein the plurality of dummy bonding connections and the bonding connection are collectively arranged in rows and columns to form a bonding connection array, wherein the bonding connection is surrounded by and adjacent to the plurality of dummy bonding connections.
